(19) United States
(12) Patent Application Publication
(10) Pub. No.: US 2018/0190845 A1
(43) Pub. Date: Jul. 5, 2018

(54) COMPOUND-BASED SOLAR CELL AND MANUFACTURING METHOD OF LIGHT ABSORPTION LAYER

(71) Applicant: Industrial Technology Research Institute, Hsinchu (TW)

(72) Inventors: Lung-Teng Cheng, Changhua County (TW); Yu-Yun Wang, Hualien County (TW); Tung-Po Hsieh, Hsinchu City (TW)

(73) Assignee: Industrial Technology Research Institute, Hsinchu (TW)

(21) Appl. No.: 15/394,816

(22) Filed: Dec. 30, 2016

(51) Int. Cl. H01L 31/032; H01L 31/0224; H01L 31/0392; H01L 31/072; H01L 31/18

(52) U.S. Cl. CPC H01L 31/0322; H01L 31/022483; H01L 31/0326; H01L 31/072; H01L 31/1864; H01L 31/03923

(57) ABSTRACT

A compound-based solar cell including a first electrode, a second electrode, a first type doped semiconductor layer and a second type doped semiconductor layer is provided. The first type doped semiconductor layer is disposed between the first electrode and the second electrode, and the second type doped semiconductor layer is disposed between the first type doped semiconductor layer and the second electrode. The first type doped semiconductor layer has a first side adjacent to the first electrode and a second side adjacent to the second type doped semiconductor layer. The first type doped semiconductor layer includes at least one of a plurality of elements, and the elements include potassium, rubidium and cesium. The concentration of at least one of the elements on the first side is higher than the concentration on the second side. Besides, a manufacturing method of a light absorption layer is also provided.

### BACKGROUND OF THE INVENTION

### 1. Field of the Invention

The disclosure is related to a solar cell, and particularly related to a manufacturing method of a compound-based solar cell and a light absorption layer.

### 2. Description of Related Art

After years of development of solar cell, the power conversion efficiency, stability and various performance indicators thereof have significant improvement. In recent years, due to the response to the development of thin solar cell, various high efficiency thin-film solar cells are also developed. Thin-film solar cell can be divided into various types according to the techniques, such as a-Si, CdTe, CIS, CIGS thin-film solar cell, etc. Among the above, the light absorption layer of the CIGS thin-film solar cell is CIGS thin film. The CIGS thin film is direct bandgap semiconductor material, and can perform light absorption in a greater solar cell spectrum range, so the CIGS thin-film solar cell has high photoelectric conversion efficiency.

Generally, after light absorption, the light absorption layer will be excited to produce electron-hole pairs, the electron and hole of the electron-hole pairs located in the p-n junction may be separated, and the electron and hole are conducted out through semiconductor material, so as to produce current. However, in the process of conducting out the electron and the hole, the probability of the recombination of the electron and hole is easily increased due to the factors such as film quality, and the photoelectric conversion efficiency of the solar cell is reduced. For keeping the good film quality to reduce the probability of electron-hole recombination, normally the method of producing the CIGS thin film use vacuum process, such as the manufacturing method of co-evaporation, two-stage selenization method, and so on. However, vacuum process can make the whole production cost of the solar cell higher, and the production time longer. Therefore, the production of high quality light absorption layer meeting the principle of low cost and fast production is one of the goals to be anxiously achieved by the researcher.

### SUMMARY OF THE INVENTION

The compound-based solar cell of the embodiment of the disclosure including a first electrode, a second electrode, a first type doped semiconductor layer and a second type doped semiconductor layer. The first type doped semiconductor layer is disposed between the first electrode and the second electrode, and the second type doped semiconductor layer is disposed between the first type doped semiconductor layer and the second electrode. The first type doped semiconductor layer has a first side adjacent to the first electrode and a second side adjacent to the second type doped semiconductor layer. The first type doped semiconductor layer includes at least one of a plurality of elements, and the elements include potassium, rubidium and cesium. The concentration of at least one of the elements on the first side is higher than the concentration on the second side.

The manufacturing method of the light absorption layer of the embodiment in the disclosure includes: forming a precursor layer on the substrate. The precursor layer includes a plurality of nanoparticles, and a material of the nanoparticles includes copper oxide, indium oxide and gallium oxide; providing the slung on the precursor layer, wherein a material of the slurry includes alkali metal compound; and performing a heat treatment on the slurry and the precursor layer.

To make the aforementioned and other features and advantages of the disclosure more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F illustrates the manufacturing flowchart of the compound-based solar cell of an embodiment in the disclosure.

FIG. 2 illustrates the elemental content analysis of the light absorption layer of the compound-based solar cell according to the embodiment of FIG. 1 at different depth.

FIG. 3A to FIG. 3D illustrates the diagram of different photoelectric conversion parameters of the compound-based solar cell versus the potassium fluoride concentration in the slurry according to the embodiment of FIG. 1F.

FIG. 4A illustrates the elemental content analysis of the light absorption layer of the compound-based solar cell with or without potassium fluoride at different depth.

FIG. 4B illustrates the I-V curve of the compound-based solar cell with or without potassium fluoride.

FIG. 5A to FIG. 5D illustrates the performance of different photoelectric conversion parameters according to the compound-based solar cell of a comparative embodiment.

FIG. 6A to FIG. 6D illustrates the performance of different photoelectric conversion parameters according to the compound-based solar cell of another comparative embodiment.

FIG. 7 illustrate the manufacturing method of the light absorption layer according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

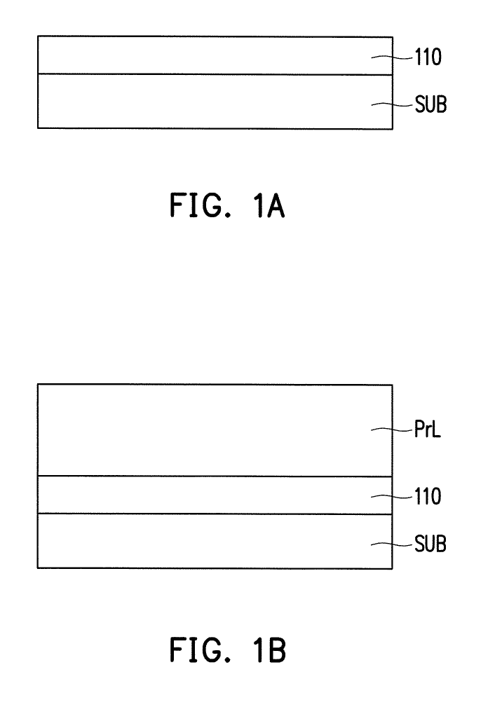

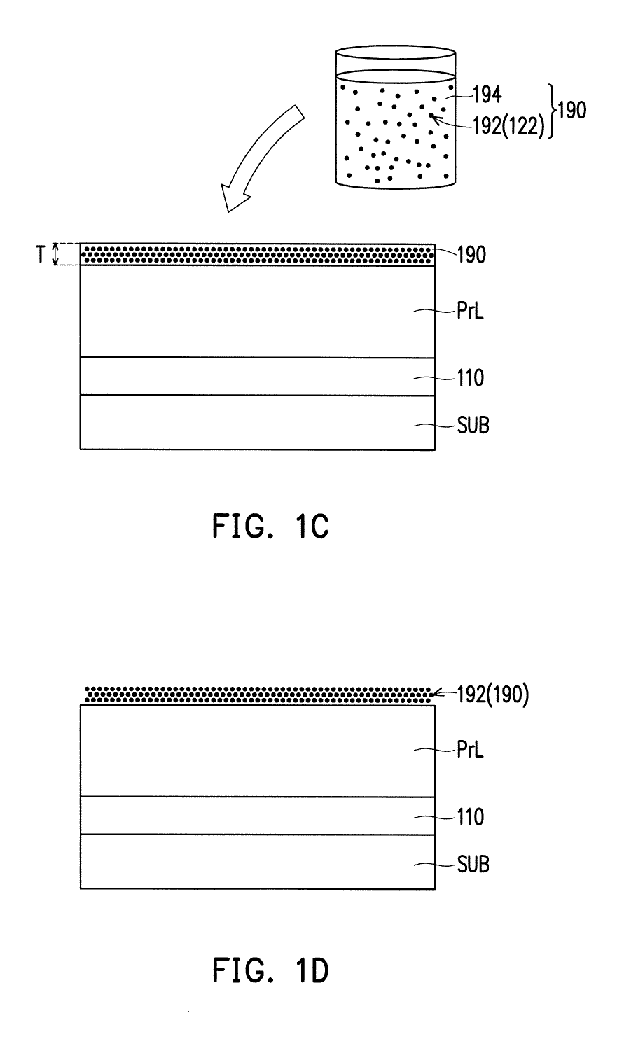

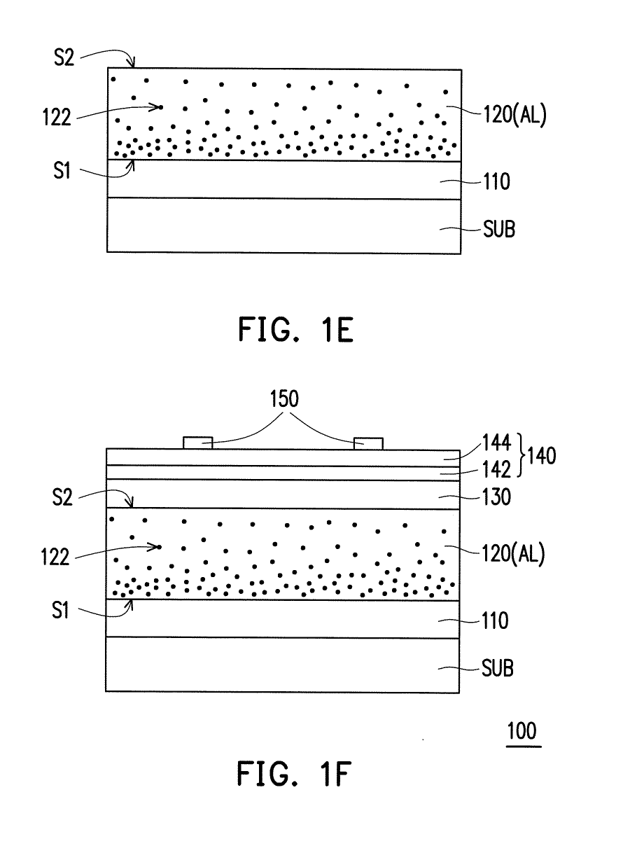

FIG. 1A to FIG. 1F illustrates the manufacturing flowchart of the compound-based solar cell of an embodiment in the disclosure, please referring to FIG. 1A first. In the embodiment, first, the substrate SUB is provided and the first electrode 110 is formed on the substrate SUB. Specifically, the first electrode 110 is used as the back electrode of the compound-based solar cell 100 (as illustrated in FIG. 1F), which can include molybdenum, silver, aluminum, chromium, titanium, nickel, gold or a combination thereof. For example, the first electrode 110 can be a molybdenum electrode plated on the substrate SUB. Then, please referring to FIG. 1B, the precursor layer PrL is formed on the substrate SUB. Specifically, the precursor layer PrL is formed on the first electrode 110, and the first electrode 110 locates between the substrate SUB and the precursor layer PrL. In the embodiment, the precursor layer PrL include a plurality of nanoparticles (NPs), and the material of the nanoparticles includes copper oxide, indium oxide and gallium oxide. Specifically, the precursor layer PrL is, for example, copper indium gallium (CIG) metal precursor, which can be, for example, copper indium gallium selenium (CIGS) thin film formed through selenization process, sulfurization process or an arbitrary combination of selenization and sulfurization. For example, the precursor layer PrL can form into the CIGS thin film through sulfurization after selenization (SAS) process, the disclosure is not limited thereto. In addition, in the embodiment, the method of forming the precursor layer PrL on the substrate SUB includes, for example, coating the precursor on the substrate SUB to form the precursor layer PrL. Through the coating method, the oxides in the precursor layer PrL can remain in the nanoparticle state. However, in some embodiments, the precursor layer PrL can be formed on the substrate SUB through other manufacturing methods, the disclosure is not limited thereto.

Then, please referring to FIG. 1C, the slurry 190 is provided on the precursor layer PrL, and the material of the slung 190 includes an alkali metal compound 192. Specifically, the slurry 190 further includes solvent 194, and the alkali metal compound 192 is evenly dispersed in the solvent 194. In detail, the alkali metal compound 192 includes at least one of a plurality of elements 122, and the elements 122 include potassium, rubidium and cesium. For example, the alkali metal compound 192 of the embodiment is potassium fluoride (KF). In addition, the solvent 194 can include, for example, water, alcohol solvent, ester solvent, ketone solvent, ether solvent, amine solvent, acid type solvent, base type solvent or a combination thereof, and the weight percent concentration of the alkali metal compound 192 in the slurry 190 lies in the range of 0.01% to 0.6%, for example. In the embodiment, the method of providing the slurry 190 on the precursor layer PrL includes coating the slung 190 on the precursor layer PrL through the capillary coating, the spin coating, the brush coating, the blade coating, the spray coating or the printing coating. Specifically, in some related embodiments, the choice of the solvent 194, the concentration of the alkali metal compound 192 in the slurry 190 and the manufacturing method of providing the slurry 190 on the precursor layer PrL can be adjusted according to the practical manufacturing requirements, the disclosure is not limited thereto. In addition, in the embodiment, the slurry 190 provided on the precursor layer PrL through coating forms into a film, and the thickness T of the film lies in the range of 3 nm to 100 nm. However, in some embodiments, according to the practical manufacturing requirements, the film of the slurry 190 coated on the precursor layer PrL can also have other thickness, the disclosure is not limited thereto.

Please referring to FIG. 1D, after the slurry 190 is provided on the precursor layer PrL, a drying treatment is performed on the slurry 190 to make the solvent 194 evaporate. Specifically, the drying treatment is, for example, performing an appropriate heating on the slurry 190 on the precursor layer PrL to make the solvent 194 evaporate, and the heating temperature thereof is, for example, less than or equal to 100 degrees celsius. Or, the slurry 190 on the precursor layer PrL can be let still for a period to make it dry naturally.

Then, please referring to FIG. 1E, in the embodiment, a heat treatment is performed on the slurry 190 and the precursor layer PrL. Specifically, the heat treatment is, for example, selenization treatment or sulfurizing after selenization treatment. In detail, the heat treatment performed on the slurry 190 and the precursor layer PrL includes: disposing the slurry 190 and the precursor layer PrL in a gas environment, wherein the gas environment includes a gas of a group VIA element. In addition, the gas environment further includes, for example, gas such as atmosphere, nitrogen, hydrogen, argon, and/or ammonia, and the pressure of the gas environment lies in, for example, a range of 10⁻⁴ torr to 760 torr. In addition, the temperature of the gas environment lies in, for example, a range of 300 degrees celsius to 600 degrees celsius, and the performing time of the heat treatment lies in, for example, a range of 1 minute to 300 minutes. In detail, appropriate gas environment can be configured according to the practical manufacturing requirements, and appropriate related parameters can be configured, the disclosure is not limited thereto.

Please continue to refer to FIG. 1E, in the embodiment, during the heat treatment process, the nanoparticles of the precursor layer PrL can, for example, grow into a CIGS crystal, and the CIGS crystal can continue to grow to form into a CIGS film. Specifically, the CIGS film is, for example, the light absorption layer AL of the compound-based solar cell 100, and is also the first type doped semiconductor layer 120 of the compound-based solar cell 100 simultaneously. In some related embodiments, through the choice of the material of the nanoparticles of the precursor layer PrL and the choice of the gas of the gas environment for performing the heat treatment, the first type doped semiconductor layer 120 can, for example, include a group IB element, a group IIIA element, a group VIA element or a combination thereof. Or, the first type doped semiconductor layer 120 can, for example, include a group IB element, a group IIB element, a group IVA element, the group VIA element or a combination thereof, the disclosure is not limited thereto. Furthermore, in detail, during the crystal growing process of the CIGS crystal of the embodiment, the element 122 of the alkali metal compound 192 can enter the CIGS crystal structure, and be distributed on the surface of CIGS thin film, in the crystal structure and the grain boundary thereof.

Please referring to FIG. 1F, in the embodiment, then, the second type doped semiconductor layer 130, the second electrode 140 and the electrode 150 are sequentially formed on the first type doped semiconductor layer 120, so that the fabrication of compound-based solar cell 100 is completed. Specifically, the compound-based solar cell 100 includes the substrate SUB, the first electrode 110, the first type doped semiconductor layer 120, the second type doped semiconductor layer 130, the second electrode 140 and the electrode 150. The first electrode 110 is disposed between the first type doped semiconductor layer 120 and the substrate SUB. The first type doped semiconductor layer 120 is disposed between the first electrode 110 and the second electrode 140, and the second type doped semiconductor layer 130 is disposed between the first type doped semiconductor layer 120 and the second electrode 140. One of the first type doped semiconductor layer 120 and the second type doped semiconductor layer 130 is N-type doped semiconductor layer, and another one of the first type doped semiconductor layer 120 and the second type doped semiconductor layer 130 is P-type doped semiconductor layer.

Specifically, the compound-based solar cell 100 is, for example, CIGS thin-film solar cell. The substrate SUB is, for example, a flexible substrate or a non-flexible substrate such as stainless steel sheet, soda-lime glass (SLG). The first type doped semiconductor layer 120 has, for example, P-type doped CIGS thin film and be configured as light absorption layer AL, and the first electrode 110 is, for example, a molybdenum back electrode adapted to form the ohmic contact with the CIGS thin film. In addition, the second type doped semiconductor layer 130 is, for example, a buffer layer having N-type doped cadmium sulfide (CdS), and the second electrode 140 includes, for example, an intrinsic zinc oxide (i-ZnO) layer 142 stacked with each other and a transparent conductive layer 144, and the intrinsic zinc oxide layer 142 is disposed between the transparent conductive layer 144 and the second type doped semiconductor layer 130. Specifically, the transparent conductive layer 144 is, for example, Al-doped zinc oxide (AZO), or transparent conductive film of other types, the disclosure is not limited thereto. Furthermore, the electrode 150 in contact with the second electrode 140 is designed into a strip shape, to avoid the light shielding. In some embodiments, the compound-based solar cell 100 can also be compound-based solar cell of other types, the disclosure is not limited thereto.

In the embodiment, the light enters the compound-based solar cell 100 from a side of the second electrode 140, for example. After the first type doped semiconductor layer 120 configured as the light absorption layer AL absorbing the light energy, the electron hole pair is produced by excitation. The p-n junction is formed between the first type doped semiconductor layer 120 and the second type doped semiconductor layer 130, and the electron and hole are separated at the electron hole pair located on the p-n junction, and the electron and hole are, for example, conducted out through the second type doped semiconductor layer 130 and the first type doped semiconductor layer 120 respectively, and received by the second electrode 140 and the first electrode 110, so as to produce the current.

Specifically, in the embodiment, the first type doped semiconductor layer 120 has a first side S1 adjacent to the first electrode 110 and a second side S2 adjacent to the second type doped semiconductor layer 130. The first type doped semiconductor layer 120 includes at least one of a plurality of elements 122 (such as the plurality of elements 122 of the alkali metal compound 192), and the elements 122 include potassium, rubidium and cesium. For example, the alkali metal compound 192 of the embodiment is potassium fluoride, and after the heat treatment, at least most of the fluorine is evaporated, so that the element 122 included by the formed first type doped semiconductor layer 120 (light absorption layer AL) is potassium, and the potassium may be distributed on the surface of the CIGS thin film, in the crystal structure and grain boundary of the first type doped semiconductor layer 120. Specifically, because at least one of the element 122 passes the gap between the nanoparticles of the precursor layer PrL and moves downward through thermal diffusion in the heat treatment process, therefore, at least one of the elements 122 can have appropriate concentration distribution in the first type doped semiconductor layer 120. In detail, the concentration of at least one of the elements 122 on the first side S1 is higher than the concentration on the second side S2. That is, in the embodiment, the concentration of the potassium distributed in the first type doped semiconductor layer 120 (light absorption layer AL) adjacent to the substrate SUB is higher than the concentration away from the substrate SUB. Specifically, the concentration of potassium distributed in the first type doped semiconductor layer 120 adjacent to the first side S1 of the first electrode 110 is higher than the concentration adjacent to the second side S2 of the second type doped semiconductor layer 130. In some embodiments, the precursor layer PrL can also be formed on the substrate SUB through the above-mentioned manufacturing method, and a light absorption layer AL is formed on the substrate SUB by the same steps in the embodiment, wherein the concentration of at least one of the elements 122 in the light absorption layer AL adjacent to the substrate SUB is higher than the concentration away from the substrate SUB.

In the embodiment, because the CIGS thin film surface, crystal structure and the grain boundary of the first type doped semiconductor layer 120 have appropriate potassium concentration distribution, therefore, the bandgap of the defect on the material interface (such as the first type doped semiconductor layer 120 and the second type doped semiconductor layer 130) or the grain boundary of the first type doped semiconductor layer 120 fall under the fermi level. That is, potassium can provide the passivation effect to the material interface and the grain boundary. When the carrier passes through the material interface or the grain boundary, the probability of the occurrence of recombination on the carrier can be reduced. Beside, in the embodiment, in the process of performing heat treatment on the slurry 190 and the precursor layer PrL to form the first type doped semiconductor layer 120 (CIGS crystal structure), the potassium occupies the vacancy of copper in the lattice first. When cadmium sulfide (second type doped semiconductor layer 130) is formed on the CIGS crystal structure by deposition, the cadmium also occupies the vacancy of copper. At this moment, the potassium originally occupying the vacancy of copper leaves, producing more vacancies of copper for cadmium to occupy. Therefore, more cadmium can occupy the vacancy of copper, so that the P/N junction between the surface of the CIGS crystal thin film and cadmium sulfide can achieve more excellent energy level matching. In the embodiment, based on the factors such as reduction of carrier recombination probability and improvement of P/N junction energy level matching, the compound-based solar cell 100 can have higher open circuit voltage (V_{oc}) and fill factor (FF) under the condition of non-vacuum process, to further possess better power conversion efficiency (PCE).

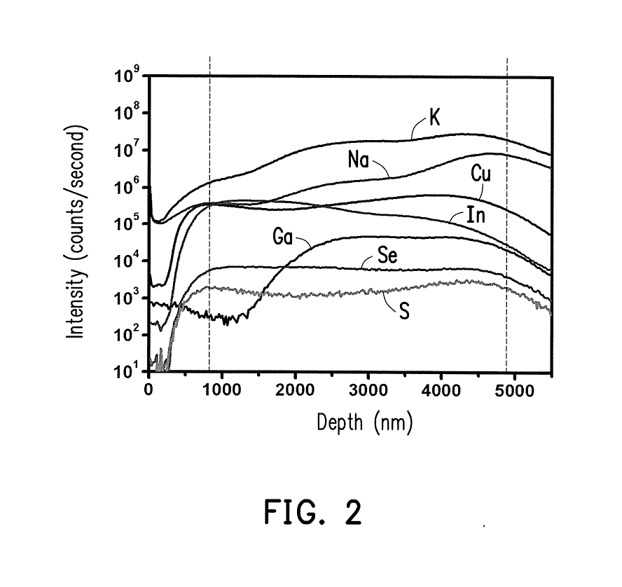

FIG. 2 illustrates the elemental content analysis of the light absorption layer of the compound-based solar cell according to the embodiment of FIG. 1 at different depth, please refer to FIG. 2. The longitudinal axis of FIG. 2 shows the magnitude of the signal measuring the elemental content of the compound-based solar cell 100, the unit thereof is counts/second, and the horizontal axis shows the depth extended toward the first electrode 110 from the second electrode 140 in the compound-based solar cell 100, the unit thereof is nanometer. The depth range defined between the two doted line shows the depth range of the first type doped semiconductor layer 120. In addition, the “S”, “Se”, “Ga”, “In”, “Cu”, “Na” and “K” marked in FIG. 2 respectively represent sulfur, selenium, gallium, indium, copper, sodium and potassium element. In the embodiment, it can be seen that the concentration of potassium distributed in the first type doped semiconductor layer 120 adjacent to a side of the first electrode 110 is approximately higher than the concentration adjacent to a side of the second type doped semiconductor layer 130.

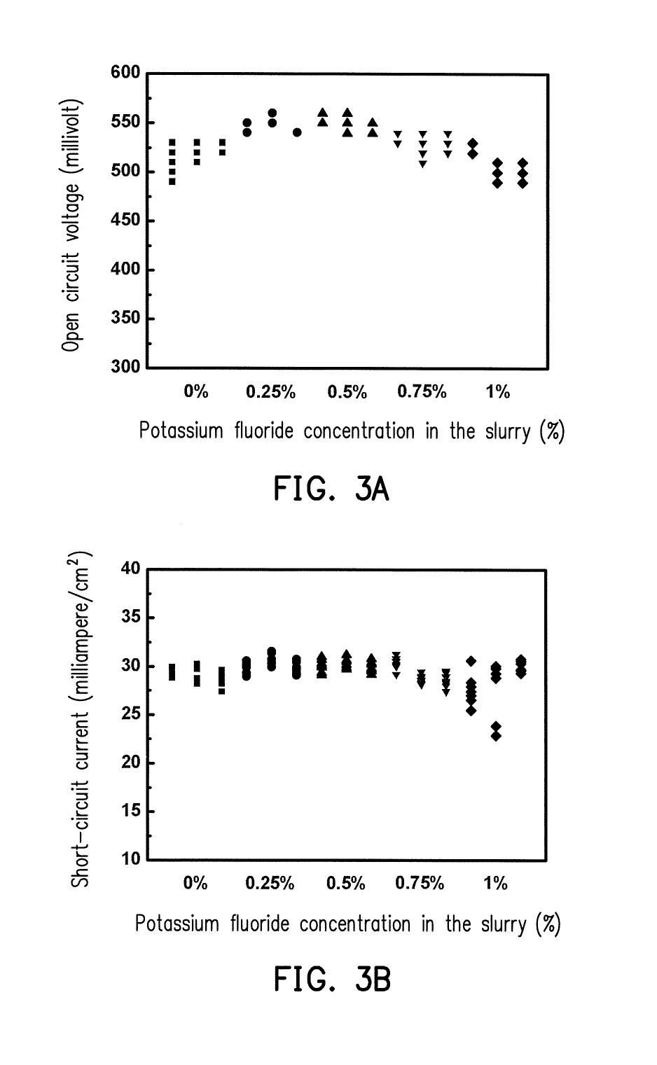

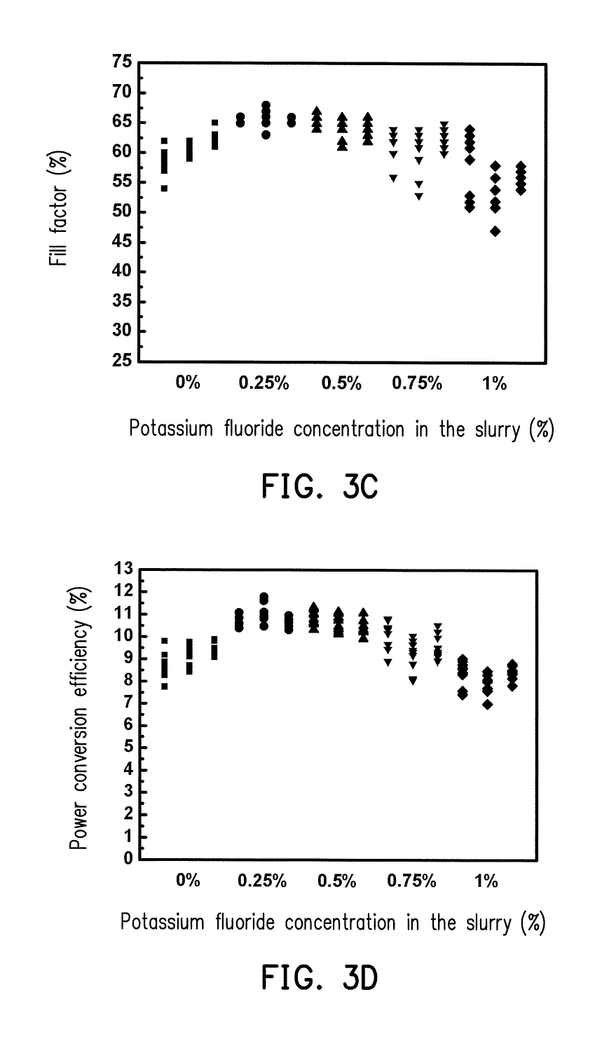

FIG. 3A to FIG. 3D illustrates the diagram of different photoelectric conversion parameters of the compound-based solar cell versus the potassium fluoride concentration in the slurry according to the embodiment of FIG. 1F, to show the photoelectric conversion performance of the compound-based solar cell 100 when slurry 190 with different potassium fluoride concentration is provided on the precursor layer PrL. In detail, FIG. 3A illustrates the diagram of the open circuit voltage of the compound-based solar cell 100 versus the concentration of potassium fluoride in the slurry 190. The longitudinal axis of FIG. 3A represents the open circuit voltage, the unit thereof is millivolt, and the horizontal axis represents the concentration of potassium fluoride in the slurry, the unit thereof is percentage. FIG. 3B illustrates the diagram of the short-circuit current of the compound-based solar cell 100 versus the concentration of potassium fluoride in the slurry. The longitudinal axis of FIG. 3B represents the short-circuit current (J_{sc}), the unit thereof is milliampere/cm², and the horizontal axis represents the concentration of potassium fluoride in the slurry, the unit thereof is percentage. FIG. 3C illustrates the diagram of the fill factor of the compound-based solar cell 100 versus the concentration of potassium fluoride in the slurry. The longitudinal axis of FIG. 3C represents the fill factor, the unit thereof is percentage, and the horizontal axis represents the concentration of potassium fluoride in the slung, the unit thereof is percentage. FIG. 3D illustrates the diagram of the power conversion efficiency of the compound-based solar cell 100 versus the concentration of potassium fluoride in the slurry. The longitudinal axis of FIG. 3D represents the power conversion efficiency, the unit thereof is percentage, and the horizontal axis represents the concentration of potassium fluoride in the slurry, the unit thereof is percentage. In FIG. 3A to FIG. 3D, the concentration of potassium fluoride in the slurry under the experimental conditions of 0%, 0.25%, 0.5%, 0.75% and 1% correspond to experimental data points marked by different shapes respectively. For example, in FIG. 3A, the experimental data points marked by circle all represent the data points obtained from different experiments with the concentration of potassium fluoride in the slurry being 0.25%. It can be shown from FIG. 3A to FIG. 3D that when the material of slurry 190 includes alkali metal compound such as potassium fluoride, the open circuit voltage and the fill factor of the compound-based solar cell 100 can both be increased, and the compound-based solar cell 100 has higher power conversion efficiency.

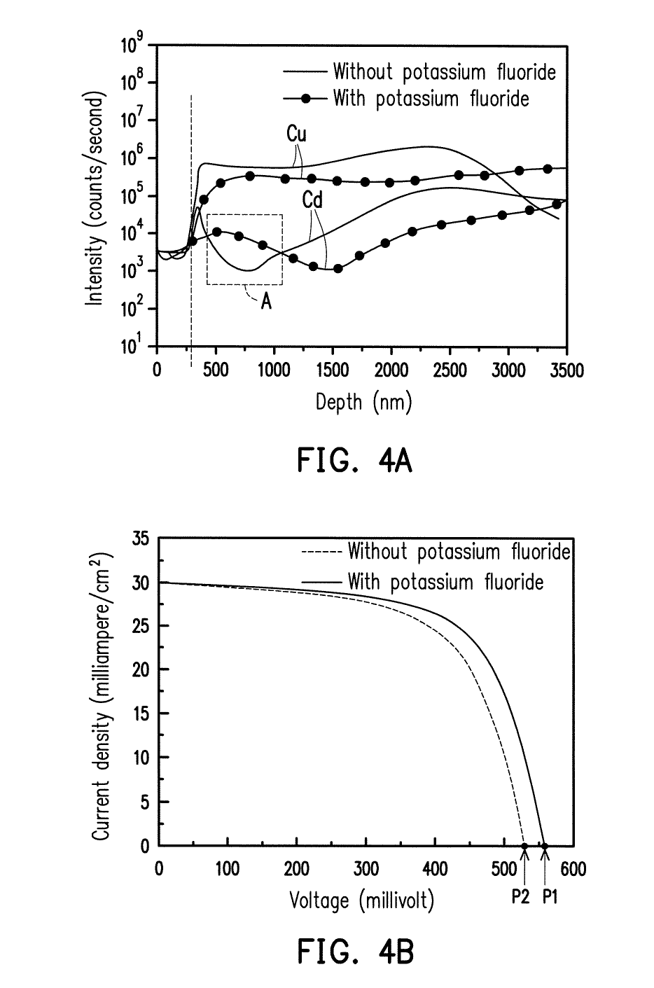

FIG. 4A illustrates the elemental content analysis of the light absorption layer of the compound-based solar cell with or without potassium fluoride at different depth, please refer to FIG. 4A. The descriptions of the marks of the longitudinal axis and the horizontal axis in FIG. 4A are the same with the descriptions of the marks of the longitudinal axis and the horizontal axis in FIG. 2 respectively, and be not repeated herein. The “Cu” and “Cd” marked in FIG. 4 respectively represent Copper and cadmium element. The curved line marked by “with potassium fluoride” represents the compound-based solar cell 100 of the embodiment in FIG. 1F, and the curved line marked by “without potassium fluoride” represents the compound-based solar cell of a comparative embodiment. In the manufacturing process of the compound-based solar cell of the comparative embodiment, the slurry including potassium fluoride is not coated on the precursor layer. In detail, the dotted line position in FIG. 4A represents the position around the P/N junction of the compound-based solar cell. It can be seen from FIG. 4A that in region A, because the first type doped semiconductor layer 120 of the compound-based solar cell 100 of the embodiment in FIG. 1F has appropriate potassium concentration distribution, therefore, more cadmium around the P/N junction can occupy the vacancy of copper, so that in region A, the cadmium content of the compound-based solar cell 100 is higher than the cadmium content of the compound-based solar cell of the comparative embodiment.

FIG. 4B illustrates the I-V curve of the compound-based solar cell with or without potassium fluoride, please refer to FIG. 4B. The longitudinal axis in FIG. 4B represents current density, the unit thereof is milliampere/cm², and the horizontal axis represent voltage, the unit thereof is millivolt. The curved line marked by “with potassium fluoride” represents the compound-based solar cell 100 of the embodiment in FIG. 1F, and the curved line marked by “without potassium fluoride” represents the compound-based solar cell of a comparative embodiment. In the manufacturing process of the compound-based solar cell of the comparative embodiment, the slurry including potassium fluoride is not coated on the precursor layer. In detail, the voltage corresponding to point P1 and point P2 are open circuit voltage of the compound-based solar cell 100 and the compound-based solar cell of the comparative embodiment respectively. It can be known from FIG. 4B that the open circuit voltage of the compound-based solar cell 100 is greater than the open circuit voltage of the compound-based solar cell of the comparative embodiment.

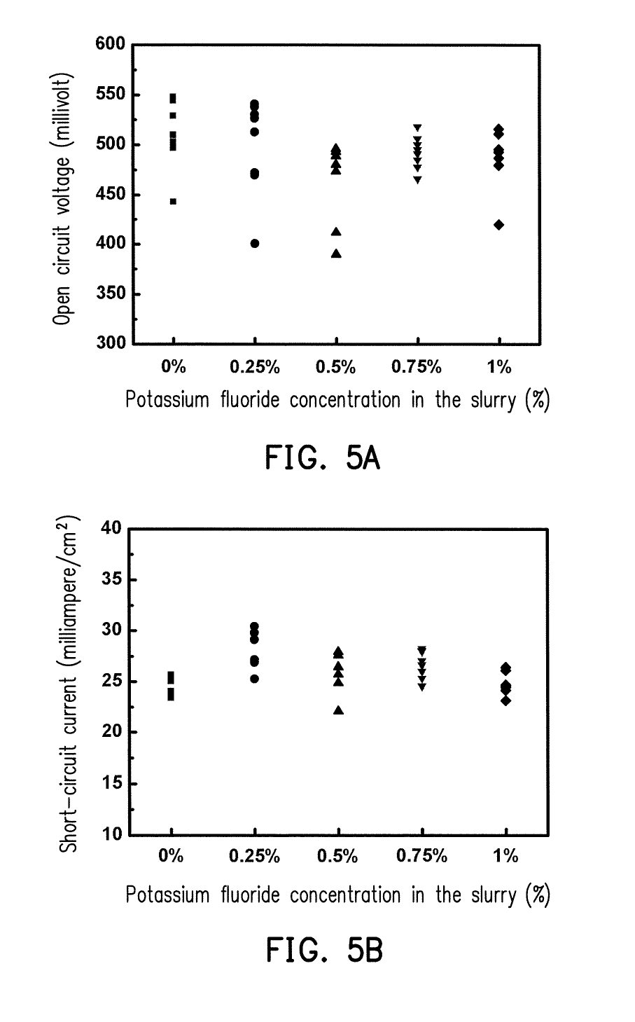

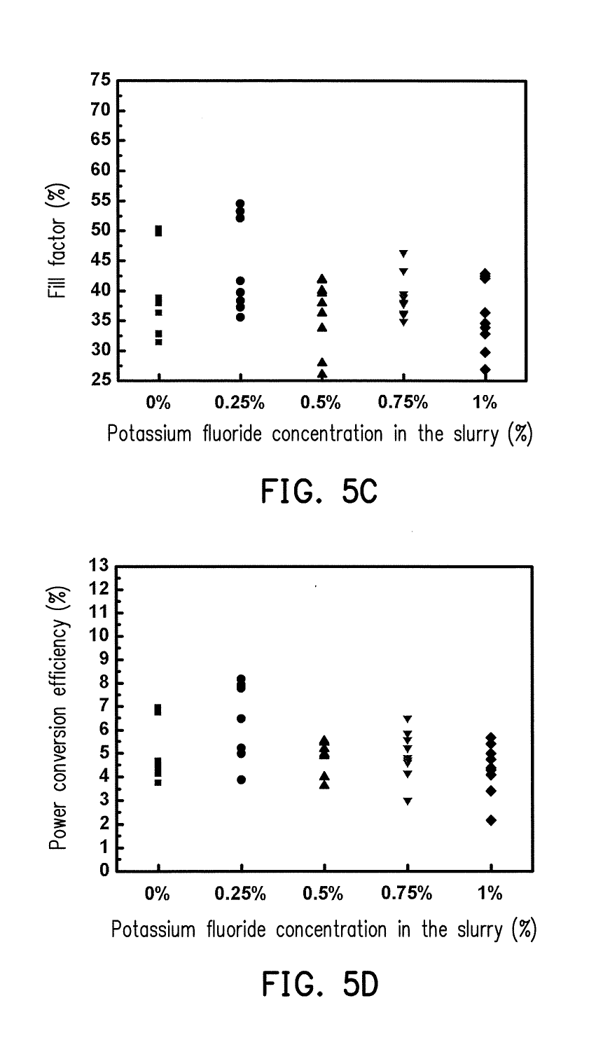

FIG. 5A to FIG. 5D illustrates the performance of different photoelectric conversion parameters according to the compound-based solar cell of a comparative example. In the manufacturing process of the compound-based solar cell of this comparative embodiment, the slurry including potassium fluoride is coated on the light absorption layer already formed by the heat treatment, and makes potassium enter the light absorption layer through annealing process. In detail, FIG. 5A illustrates the diagram of the open circuit voltage of the compound-based solar cell versus the concentration of potassium fluoride in the slurry according to the comparative embodiment. The longitudinal axis of FIG. 5A represents the open circuit voltage, the unit thereof is millivolt, and the horizontal axis represents the concentration of potassium fluoride in the slurry, the unit thereof is percentage. FIG. 5B illustrates the diagram of the short-circuit current of the compound-based solar cell versus the concentration of potassium fluoride in the slurry according to the comparative embodiment. The longitudinal axis of FIG. 5B represents the short-circuit current, the unit thereof is milliampere/cm², and the horizontal axis represents the concentration of potassium fluoride in the slurry, the unit thereof is percentage. FIG. 5C illustrates the diagram of the fill factor of the compound-based solar cell versus the concentration of potassium fluoride in the slung according to the comparative embodiment. The longitudinal axis of FIG. 5C represents the fill factor, the unit thereof is percentage, and the horizontal axis represents the concentration of potassium fluoride in the slurry, the unit thereof is percentage. FIG. 5D illustrates the diagram of the power conversion efficiency of the compound-based solar cell versus the concentration of potassium fluoride in the slurry according to the comparative embodiment. The longitudinal axis of FIG. 5D represents the power conversion efficiency, the unit thereof is percentage, and the horizontal axis represents the concentration of potassium fluoride in the slurry, the unit thereof is percentage. Compare FIG. 3A-FIG. 3D to FIG. 5A-FIG. 5D, it can be known that the compound-based solar cell 100 has better device performance, and the compound-based solar cell 100 has higher power conversion efficiency.

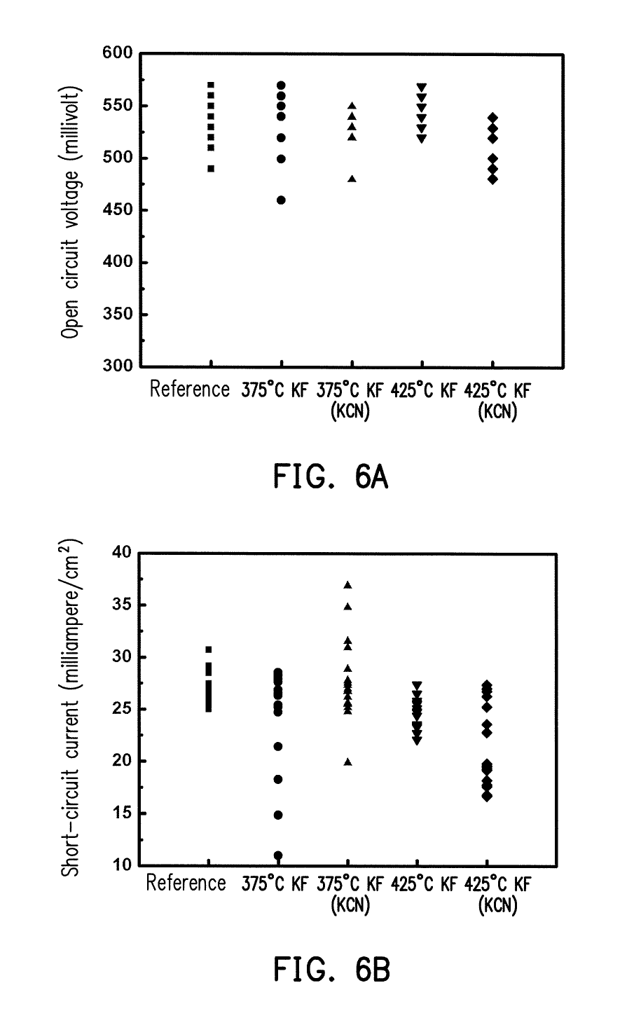

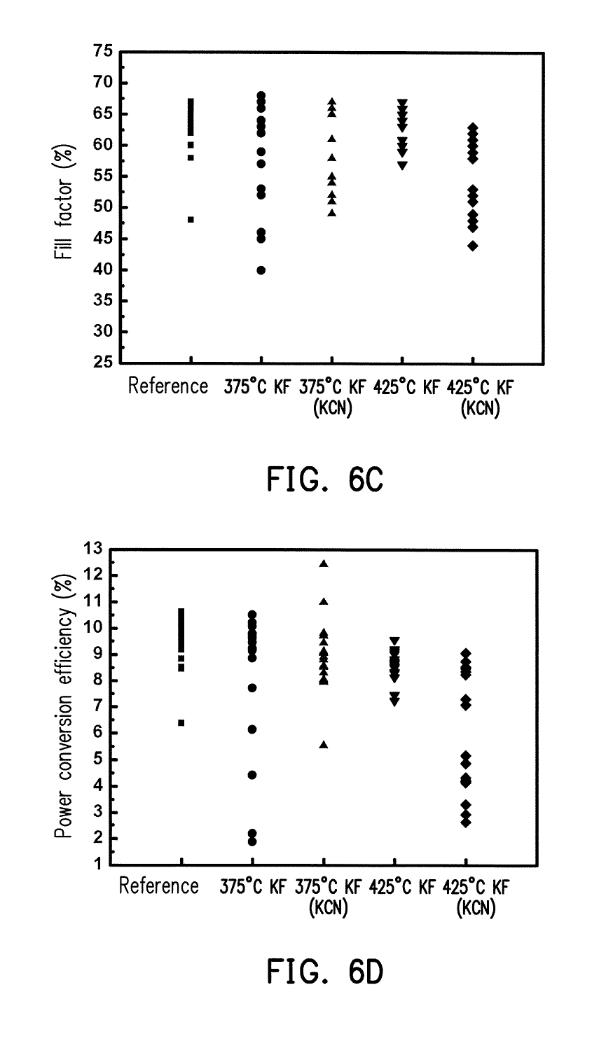

FIG. 6A to FIG. 6D illustrates the performance of different photoelectric conversion parameters according to the compound-based solar cell of another comparative embodiment. In the manufacturing process of the compound-based solar cell in this comparative embodiment, potassium fluoride enters the light absorption layer formed by the heat treatment through the method of vacuum vapor deposition and annealing. In detail, FIG. 6A illustrates the diagram of the open circuit voltage of the compound-based solar cell versus different annealing temperatures according to the comparative embodiment. The longitudinal axis of FIG. 6A represents the open circuit voltage, the unit thereof is millivolt, and the horizontal axis represent different annealing temperatures. FIG. 6B illustrates the diagram of the short-circuit current of the compound-based solar cell versus different annealing temperatures according to the comparative embodiment. The longitudinal axis of FIG. 6B represents the short-circuit current, the unit thereof is milliampere/cm², and the horizontal axis represent different annealing temperatures. FIG. 6C illustrates the diagram of the fill factor of the compound-based solar cell versus different annealing temperatures according to the comparative embodiment. The longitudinal axis of FIG. 6C represents the fill factor, the unit thereof is percentage, and the horizontal axis represent different annealing temperatures. FIG. 6D illustrates the diagram of the power conversion efficiency of the compound-based solar cell versus different annealing temperatures according to the comparative embodiment. The longitudinal axis of FIG. 6D represents the power conversion efficiency, the unit thereof is percentage, and the horizontal axis represent different annealing temperatures. In addition, in FIG. 6A to FIG. 6D, the mark “reference” represents the control group conditions of the control group without the vapor deposition of potassium fluoride. The mark “375° C. KF” represents the substrate temperature being 375 degrees celsius when potassium fluoride is vapor deposited on the CIGS surface. The mark “375° C. KF (KCN)” represents that after the CIGS surface is etched by potassium cyanide, the etched surface thereof is vapor deposited by potassium fluoride, and the substrate temperature is 375 degrees celsius when potassium fluoride is being deposited. The mark “425° C. KF” represents the substrate temperature being 425 degrees celsius when potassium fluoride is vapor deposited on the CIGS surface. In addition, the mark “425° C. KF (KCN)” represents that after the CIGS surface is etched by potassium cyanide, the etched surface thereof is vapor deposited by potassium fluoride, and the substrate temperature is 425 degrees celsius when potassium fluoride is being deposited. Specifically, comparing FIG. 3A-FIG. 3D to FIG. 6A-FIG. 6D, it can be known that the compound-based solar cell 100 has better device performance, and the compound-based solar cell 100 has higher power conversion efficiency.

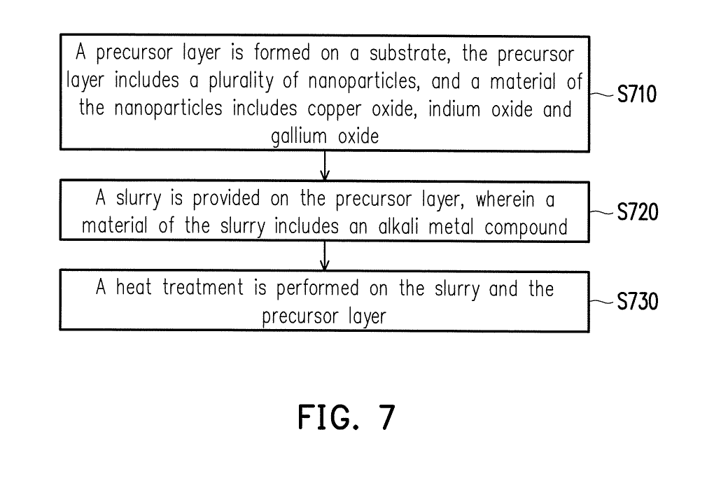

FIG. 7 illustrate the manufacturing method of the light absorption layer according to an embodiment of the disclosure, please refer to FIG. 7. In the embodiment, the manufacturing method of the light absorption layer can at least be applied on the light absorption layer AL (first type doped semiconductor layer 120) of the compound-based solar cell 100 of the embodiment in FIG. 1F. The manufacturing method of the light absorption layer are the following steps. In step S710, a precursor layer is formed on a substrate, the precursor layer includes a plurality of nanoparticles, and a material of the nanoparticles includes copper oxide, indium oxide and gallium oxide. In the step S720, a slurry is provided on the precursor layer, wherein a material of the slurry includes an alkali metal compound. In addition, in the step S730, a heat treatment is performed on the slurry and the precursor layer. Specifically, enough teaching, recommendations and description about the manufacturing method of the light absorption layer of the embodiment in the disclosure can at least be obtained from the description of the embodiments in FIG. 1A to FIG. 1F, and are not repeated herein.

Based on the above, in the manufacturing method of the light absorption layer, the precursor layer includes a plurality of nanoparticles, and the material of the nanoparticles includes copper oxide, indium oxide and gallium oxide. In addition, the manufacturing method of the light absorption layer includes providing a slurry on the precursor layer, and the material of the slurry includes an alkali metal compound. The light absorption layer produced by the above-mentioned manufacturing method are used as the first type doped semiconductor layer in the compound-based solar cell of the embodiment in the disclosure, therefore, the first type doped semiconductor layer includes at least one of the plurality of elements, and the elements include alkali metal elements such as potassium, rubidium and cesium. In addition, at least one of the alkali metal elements have appropriate concentration distribution in the first type doped semiconductor layer. Because alkali metal element can be distributed on the surface of light absorption layer, in the crystal structure and grain boundary in the process of the heat treatment such as selenization, sulfurization, or arbitrary combination of selenization and sulfurization, so that the passivation effect on the material interface of light absorption layer and grain boundary can be produced, so as to reduce the probability of the recombination of electron and hole. In addition, more excellent energy level matching can be achieved on the P/N junction. Therefore, the compound-based solar cell can have higher open circuit voltage and fill factor under the adoption of non-vacuum manufacturing process, so as to possess better power conversion efficiency.

It will be apparent to those skilled in the art that various modifications and variations can be made to the disclosed embodiments without departing from the scope or spirit of this disclosure. In view of the foregoing, it is intended that the disclosure covers modifications and variations provided that they fall within the scope of the following claims and their equivalents.

1. A compound-based solar cell, comprising:
a first electrode;
a second electrode;
a first type doped semiconductor layer, disposed between the first electrode and the second electrode, and a second type doped semiconductor layer, disposed between the first type doped semiconductor layer and the second electrode, wherein the first type doped semiconductor layer has a first side adjacent to the first electrode and a second side adjacent to the second type doped semiconductor layer, the first type doped semiconductor layer comprises at least one of a plurality of elements, and the elements comprises potassium, rubidium and cesium, wherein a concentration of at least one of the elements on the first side is higher than a concentration on the second side.

2. The compound-based solar cell according to claim 1, wherein the first type doped semiconductor layer comprises a group IB element, a group IIIA element, a group VIA element or a combination thereof, or the group IB element, a group IIB element, a group IVA element, the group VIA element or a combination thereof.

3. The compound-based solar cell according to claim 1, wherein the first electrode comprises molybdenum, silver, aluminum, chromium, titanium, nickel, gold or a combination thereof.

4. The compound-based solar cell according to claim 1, wherein one of the first type doped semiconductor layer and the second type doped semiconductor layer is P-type doped semiconductor layer, and the other one of the first type doped semiconductor layer and the second type doped semiconductor layer is N-type doped semiconductor layer.

5. The compound-based solar cell according to claim 1, further comprising a substrate, and the first electrode is disposed between the first type doped semiconductor layer and the substrate.

6. A manufacturing method of a light absorption layer, comprising:
forming a precursor layer on a substrate, wherein the precursor layer comprises a plurality of nanoparticles, and a material of the nanoparticles comprises copper oxide, indium oxide and gallium oxide;
providing a slung on the precursor layer, wherein a material of the slurry comprises an alkali metal compound; and
performing a heat treatment on the slurry and the precursor layer.

7. The manufacturing method of the light absorption layer according to claim 6, wherein a method of forming the precursor layer on the substrate comprises:
coating a precursor on the substrate to form the precursor layer.

8. The manufacturing method of the light absorption layer according to claim 6, wherein a method of providing the slurry on the precursor layer comprises:
coating the slung on the precursor layer through capillary coating, spin coating, brush coating, blade coating, spray coating or printing coating.

9. The manufacturing method of the light absorption layer according to claim 6, wherein the slurry further comprises a solvent, and the alkali metal compound is evenly dispersed in the solvent.

10. The manufacturing method of the light absorption layer according to claim 9, wherein the solvent comprises water, alcohol solvent, ester solvent, ketone solvent, ether solvent, amine solvent, acid type solvent, base type solvent or a combination thereof.

11. The manufacturing method of the light absorption layer according to claim 6, wherein a weight percent concentration of the alkali metal compound in the slurry lies in a range between 0.01% and 0.6%.

12. The manufacturing method of the light absorption layer according to claim 9, further comprising:
after providing the slurry on the precursor layer, performing a drying treatment on the slurry to make the solvent evaporate.

13. The manufacturing method of the light absorption layer according to claim 6, wherein the alkali metal compound comprises at least one of a plurality of elements, and the elements comprise potassium, rubidium and cesium.

14. The manufacturing method of the light absorption layer according to claim 6, wherein the slurry provided on the precursor layer forms a layer, and a thickness of the layer lies in a range of 3 nm to 100 nm.

15. The manufacturing method of the light absorption layer according to claim 13, wherein a method of performing the heat treatment on the slurry and the precursor layer comprises:
disposing the slurry and the precursor layer in a gas environment to form a light absorption layer, wherein the gas environment comprises a gas of a group VIA element, and a temperature of the gas environment lies in a range of 300 degrees celsius to 600 degrees celsius.

16. The manufacturing method of the light absorption layer according to claim 15, wherein the light absorption layer comprises at least one of the elements, and a concentration of at least one of the elements adjacent to the substrate is greater than a concentration away from the substrate.
